(19) United States
(12) Patent Application Publication
(10) Pub. No.: US 2017/0302228 A1
(43) Pub. Date: Oct. 19, 2017

(54) DIGITAL-TO-RF POWER CONVERTER

(71) Applicant: CommScope Technologies LLC, Hickory, NC (US)

(72) Inventor: George VELLA-COLEIRO, Summit, NJ (US)

(21) Appl. No.: 15/515,676

(22) PCT Filed: Jan. 22, 2015
(86) PCT No.: PCT/US2015/012424

§ 371 Date: Mar. 30, 2017

Related U.S. Application Data
(60) Provisional application No. 62/058,724, filed on Oct. 2, 2014.

(51) Int. Cl. H03F 1/02; H03F 1/56; H03F 3/217; H03H 11/32

(52) U.S. Cl. CPC H03F 1/0244; H03H 11/32; H03F 1/565; H03F 3/217; H03F 2200/387

(57) ABSTRACT

A power converter converts a digital input signal into an RF output power signal. A digital signal processor converts the input signal into one or more copies of a multi-bit RF signal. Each copy of the multi-bit RF signal is applied to a corresponding multi-bit current generator having a set of weighted, switched current sources, each of which is controlled by a different bit of the multi-bit RF signal. The currents from the different current sources are processed and combined to generate the output power signal.

### Cross-Reference to Related Applications

This application claims the benefit of the filing date of U.S. provisional application No. 62/058,724, filed on Oct. 2, 2014 as attorney docket no. Inventor 1052.130PROV, the teachings of which are incorporated herein by reference in their entirety.

### BACKGROUND

Field of the Invention

The present invention relates to electronics and, more specifically but not exclusively, to circuitry for converting digital input signals into RF (radio frequency) power output signals.

Description of the Related Art

This section introduces aspects that may help facilitate a better understanding of the invention. Accordingly, the statements of this section are to be read in this light and are not to be understood as admissions about what is prior art or what is not prior art.

The architecture of current-generation wireless communications transmitters includes a dual digital-to-analog converter (DAC) that converts the I and Q components of a complex digital baseband signal into a low-level intermediate frequency (IF), which is then up-converted to the desired radio frequency (RF). The low-level RF signal is then amplified to the desired power level, filtered, and sent to the transmit antenna. The design of the final stage of the power amplifier has evolved from Class AB to Doherty and Asymmetrical Doherty, with Class F and Inverse Class F designs in the offing, in order to improve the power efficiency of the amplifier. In spite of these advances, the power amplifier still dissipates a considerable amount of power as heat, which necessitates the use of a large heat sink to avoid excessive temperature rise. Additionally, the output stage of the amplifier is highly non-linear so that linearization by, for example, digital pre-distortion is required to avoid transmitting spurious signals.

Switching amplifiers (Class D) have been studied for decades, and, in recent years, they have become widely used as audio amplifiers because of their very high power efficiency, small size, and good linearity. In this type of amplifier, output transistors are used as switches that are either completely on or completely off so that there is very little power dissipated in the transistors. The audio signal is converted to a one-bit digital stream using pulse-width modulation or delta-sigma modulation. To reproduce the audio signal with high fidelity, the sampling rate of the digital bit stream must be much higher than the highest frequency being amplified, which is typically 20 KHz. A commonly used sampling frequency is 1 MHz, and power efficiencies greater than 95% are achievable.

Although the advantages of Class D amplifiers for RF applications have been appreciated for a long time, adoption of the technique faces a number of hurdles. For an output frequency of 2 GHz, the sampling rate has to be greater than 8 GHz, which is achievable with small-signal transistors, but it becomes increasingly difficult as the power level increases due to the parasitic inductance and capacitance associated with the transistor structure and its package.

Another hurdle is achieving the high efficiency of which a Class D amplifier is potentially capable. Since RF spectrum is available in frequency bands, the digital converter of choice is the delta-sigma modulator which can be designed to have bandpass characteristics. A delta-sigma modulator has noise-shaping properties that produce a low noise level within the pass band and a rapid increase in noise level outside the pass band. The out-of-band noise should be removed before the signal is transmitted. If a conventional RF filter is used for this purpose, then the power in the out-of-band noise can be dissipated in a 50-ohm load but only with a reduction in efficiency. To achieve high efficiency, the out-of-band power has to be returned to the power supply. There is currently no satisfactory solution to this problem.

### BRIEF DESCRIPTION OF THE DRAWINGS

Other embodiments of the invention will become more fully apparent from the following detailed description, the appended claims, and the accompanying drawings in which like reference numerals identify similar or identical elements.

FIG. 1 is a simplified block diagram of a digital-to-RF power converter according to one embodiment of the disclosure;

FIG. 2 is a simplified circuit diagram of each single-ended-to-differential converter of FIG. 1; and

FIG. 3 is a simplified schematic diagram of a 2:1 Wilkinson combiner that can be used to implement the RF combiner of FIG. 1.

### DETAILED DESCRIPTION

This disclosure describes a technique for converting a digital signal directly to an RF signal with the desired power level, thus eliminating the need for analog RF power amplification and linearization.

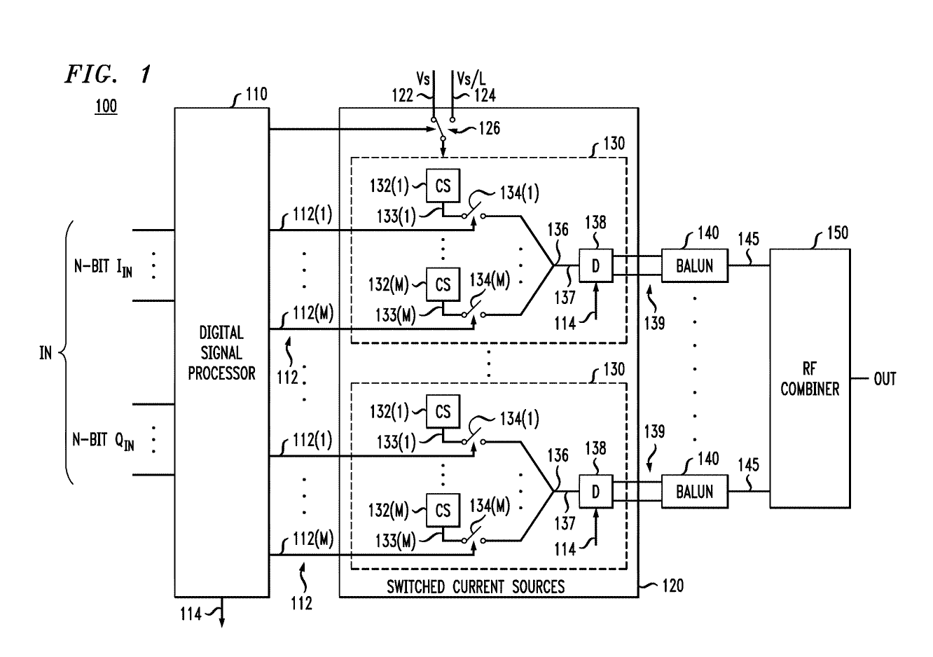

FIG. 1 is a simplified block diagram of a digital-to-RF power converter 100 according to one embodiment of the disclosure. Power converter 100 receives a complex, digital, baseband, input signal IN consisting of a sequence of N-bit in-phase components I_{IN} and a corresponding sequence of N-bit quadrature components Q_{IN} and generates an RF output power signal OUT. Although shown in FIG. 1 as two parallel data streams, the input signal IN can be applied in other forms such as single-lane or multi-lane serialized data.

The complex input signal IN is applied to digital signal processor (DSP) 110, which, depending on the particular implementation, applies a sequence of various digital signal processing techniques to the input signal IN to generate a digital RF signal represented by one or more identical copies of a real, unsigned, multi-bit (i.e., M-bit, M>1), coded, digital, RF signal 112 corresponding to the absolute value of the digital RF signal and a one-bit control signal 114 corresponding to the sign of the digital RF signal. The various digital signal processing techniques may include, among others, serial-to-parallel conversion, equalization, interpolation, filtering, and mixing with the output of an onboard numerically controlled oscillator (not shown).

The one or more copies of M-bit RF signal 112 generated by DSP 110 are applied to an array 120 of switched current sources. In particular, each copy of M-bit RF signal 112 is applied to a different instance of a multi-bit current generator 130 consisting of M weighted constant current sources 132(1)-132(M), M corresponding transistor switches 134(1)-134(M), a current summation node 136, and a single-ended-to-differential converter 138. As described further below, when DSP 110 generates multiple copies of RF signal 112 and when array 120 has a corresponding number of multi-bit current generators 130, the use of multiple multi-bit current generators 130 is intended to reduce the maximum current that needs to be switched within array 120 for the required level of RF power output.

For each copy of M-bit RF signal 112, each bit 112(i) is used to control a corresponding switch 134(i) of an associated current source 132(i) in the corresponding multi-bit current generator 130. If the value of the bit 112(i) is logic zero, then the switch 134(i) is open. If the value of the bit 112(i) is logic one, then the switch 134(i) is closed. The currents from any current sources 132 having closed switches 134 are summed at current summation node 136, and the resulting single-ended, unipolar summed current signal 137 is applied to single-ended-to-differential converter 138, which converts the unipolar summed current signal 137 into two complementary components of a differential, bipolar current signal 139.

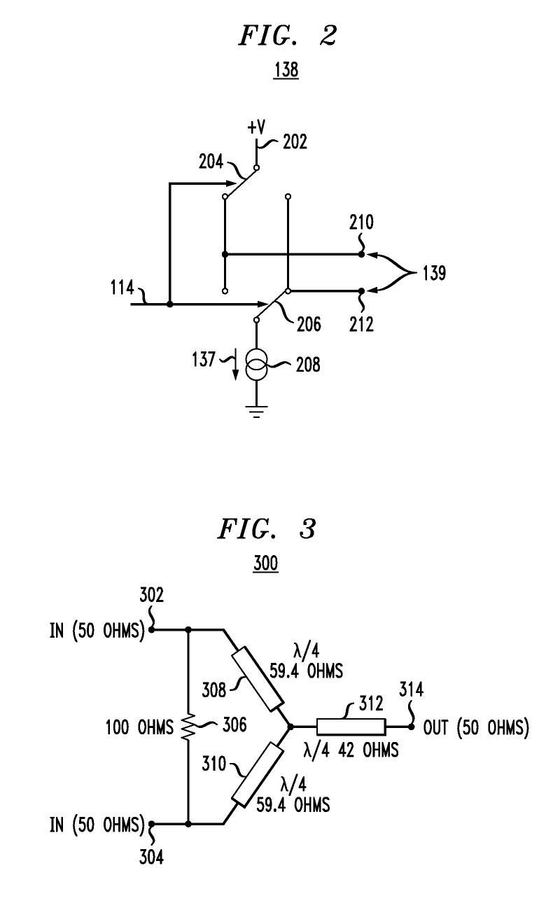

FIG. 2 is a simplified circuit diagram of each single-ended-to-differential converter 138 of FIG. 1. Converter 138 receives the corresponding unipolar summed current signal 137 from FIG. 1 and generates the differential current signal 139 at the two ports 210 and 212, which are connected across a load, i.e., balun 140 of FIG. 1. As shown in FIG. 2, converter 138 has two switches: switch 204 which selectively connects a positive voltage supply 202 to either port 210 or port 212 and switch 206 which selectively connects a grounded current source 208 which applies the unipolar summed current signal 137 to the other of port 210 and port 212. In other words, when switch 204 is configured to connect voltage supply 202 to port 210, switch 206 is configured to connect current source 208 to port 212, and vice versa.

The states of the two switches 204 and 206 are controlled by the one-bit control signal 114 generated by DSP 110 of FIG. 1 (corresponding to the sign of the digital RF signal generated by DSP 110). In particular, when control signal 114 is at logic 0 (indicating a positive sign of the digital RF signal), switch 204 is configured to connect voltage supply 202 to port 210 and switch 206 is configured to connect current source 208 to port 212. In that case, current flows from the voltage supply 202 through switch 204 out port 210 through the load into port 212 through switch 206 and current source 208 to ground. When control signal 114 is at logic 1 (indicating a negative sign of the digital RF signal), switch 204 is configured to connect voltage supply 202 to port 212 and switch 206 is configured to connect current source 208 to port 210. In that case, current flows from the voltage supply 202 through switch 204 out port 212 through the load into port 210 through switch 206 and current source 208 to ground. In this way, the unipolar summed current signal 137 is converted into the bipolar, differential current signal 139.

The particular coding scheme used for the M-bit RF signal 112 determines the relative sizes of the currents 133(1)-133(M) generated by the different weighted current sources 132(1)-132(M) in each multi-bit current generator 130. For straight binary coding in which each successive bit represents twice the value of the preceding bit, each successive current source 132(i+1) generates a current that is twice as large as the current generated by the preceding current source 132(i). Thus, the set of currents {133(1), 133(2), 133(3), . . . , 133(M−1), 133(M)} would be proportional to {2⁰, 2¹, 2², . . . , 2^{M}^{_{−1}}, 2^{M}^{_{−2}}}. Other coding schemes would have other corresponding current relationships, including splitting the most significant bit (MSB) into two or more current sources 132 in order to reduce the value of the largest current that needs to be switched. This process can be applied to more than one high-order bits, trading off maximum switched current for the number of current sources.

As shown in FIG. 1, each differential current signal 139 generated by a corresponding multi-bit current generator 130 in array 120 is applied to a corresponding balun (balanced-to-unbalanced) converter 140 that converts the differential current signal 139 into a single-ended bipolar RF signal 145. The outputs of the balun converters 140 are single-ended bipolar RF signals 145, which can be used in the conventional way. In particular, the single-ended bipolar RF signals 145 from the different balun converters 140 are applied to RF combiner 150, which adds the individual signals 145 together while maintaining a constant impedance to generate the high-level RF output power signal OUT.

FIG. 3 is a simplified schematic diagram of 2:1 Wilkinson combiner 300 that can be used to implement RF combiner 150 of FIG. 1. Combiner 300 combines two single-ended bipolar RF signals applied to input ports 302 and 304 to generate a combined single-ended bipolar RF signal at output port 314. For conventional 50-ohm impedance matching, resistor 306 has a resistance of 100 ohms, quarter-wave transmission lines 308 and 310 have a characteristic impedance of 59.4 ohms each, and quarter-wave transmission line 312 has a characteristic impedance of 42 ohms.

If, for example, array 120 has two instances of multi-bit current generator 130, then RF combiner 150 can be implemented with a single instance of 2:1 combiner 300 of FIG. 3 that receives and combines the single-ended bipolar RF signals 145 from the two baluns 140 to generate the RF output power signal OUT. If, on the other hand, array 120 has four instances of multi-bit current generator 130, then RF combiner 150 can be implemented as a two-stage combiner having three instances of 2:1 combiner 300 of FIG. 3: two instances each combining a different pair of the single-ended bipolar RF signals 145 from the four baluns 140 and a third instance to combine the outputs of those first two instances to generate the RF output power signal OUT. Those skilled in the art will understand how to extend this architecture to implement RF combiner 150 for other numbers of instances of multi-bit current generator 130, including odd numbers.

Note that, for embodiments having only one multi-bit current generator 130 in array 120 of FIG. 1, RF combiner 150 is not needed, and the single-ended bipolar RF signal 145 generated by the single balun converter 140 will be the RF output power signal OUT for that embodiment of digital-to-RF power converter 100.

If the desired peak level of RF output power signal OUT is, for example, 1 watt into 50 Ohms, then the maximum switched current for a single-bit switching amplifier would be about 7A, which is virtually impossible to switch at the high rates required to generate multi-GHz signals. For a power converter of the present disclosure having an array 120 of four multi-bit current generators 130 employing straight binary coding, the maximum switched current would be less than 1A, which could be reduced further by modifying the coding scheme as described above. The reduced maximum switched current level makes it possible to achieve the desired high switching speed.

An important consideration is the power efficiency of converting a multi-bit digital signal into a current. If all the current sources are powered by a single voltage source, then the efficiency is dependent on the peak-to-average power ratio (PAPR) of the signal. In modern wireless communications systems, the PAPR is typically 6 dB, which results in an efficiency of about 50%. A higher efficiency can be achieved by providing more than one voltage supply for the current sources.

For example, power converter 100 has two voltage supplies 122 and 124 providing supply voltage levels of Vₛ and Vₛ/L (L>1), respectively, and a switch 126 controlled by DSP 110 to select one of the two supply voltage levels according to whether the digital signal value is greater than full scale divided by L or not. In particular, the greater supply voltage level Vₛ is selected when the digital signal value is greater than full scale divided by L; otherwise, the smaller supply voltage level Vₛ/L is selected. By adopting this scheme, the efficiency can be increased to about 70%, where the value of L is chosen to optimize the efficiency. For example, L≈1.5 for a PAPR of 6 dB. A further increase in efficiency can be achieved by using more than two voltage supplies.

In certain implementations of power converter 100, DSP 110 and array 120 are implemented using two different semiconductor technologies. For example, in possible implementations, DSP 110 is implemented in a first integrated circuit (IC) die employing conventional silicon technology, while array 120 is implemented in a second IC die employing a gallium nitride, gallium arsenide, or indium phosphide technology that supports faster switching of greater current levels than does conventional silicon technology. Since they would typically occupy too much area to be included on either the first or second IC dies, the baluns 140 and the RF combiner 150 would typically be implemented on a separate ceramic substrate.

Although power converter 100 receives a complex input signal IN consisting of I_{IN} and Q_{IN} components, in other embodiments of the disclosure, a power converter could receive a real input signal consisting of a single, real component. Furthermore, although power converter 100 receives a baseband input signal IN, in other embodiments of the disclosure, a power converter could receive a digital IF or even RF input signal. In all of these cases, the processing performed by the DSP would be suitably different, but the circuitry downstream of the DSP could be identical to that of power converter 100.

Embodiments of the invention may be implemented as (analog, digital, or a hybrid of both analog and digital) circuit-based processes, including possible implementation as a single integrated circuit (such as an ASIC or an FPGA), a multi-chip module, a single card, or a multi-card circuit pack. As would be apparent to one skilled in the art, various functions of circuit elements may also be implemented as processing blocks in a software program. Such software may be employed in, for example, a digital signal processor, micro-controller, general-purpose computer, or other processor.

Also for purposes of this description, the terms “couple,” “coupling,” “coupled,” “connect,” “connecting,” or “connected” refer to any manner known in the art or later developed in which energy is allowed to be transferred between two or more elements, and the interposition of one or more additional elements is contemplated, although not required. Conversely, the terms “directly coupled,” “directly connected,” etc., imply the absence of such additional elements.

Signals and corresponding nodes, ports, or paths may be referred to by the same name and are interchangeable for purposes here.

The functions of the various elements shown in the figures, including any functional blocks labeled as “processors,” may be provided through the use of dedicated hardware as well as hardware capable of executing software in association with appropriate software. When provided by a processor, the functions may be provided by a single dedicated processor, by a single shared processor, or by a plurality of individual processors, some of which may be shared. Moreover, explicit use of the term “processor” or “controller” should not be construed to refer exclusively to hardware capable of executing software, and may implicitly include, without limitation, digital signal processor (DSP) hardware, network processor, application specific integrated circuit (ASIC), field programmable gate array (FPGA), read only memory (ROM) for storing software, random access memory (RAM), and non volatile storage. Other hardware, conventional and/or custom, may also be included. Similarly, any switches shown in the figures are conceptual only. Their function may be carried out through the operation of program logic, through dedicated logic, through the interaction of program control and dedicated logic, or even manually, the particular technique being selectable by the implementer as more specifically understood from the context.

It should be appreciated by those of ordinary skill in the art that any block diagrams herein represent conceptual views of illustrative circuitry embodying the principles of the invention. Similarly, it will be appreciated that any flow charts, flow diagrams, state transition diagrams, pseudo code, and the like represent various processes which may be substantially represented in computer readable medium and so executed by a computer or processor, whether or not such computer or processor is explicitly shown.

Unless explicitly stated otherwise, each numerical value and range should be interpreted as being approximate as if the word “about” or “approximately” preceded the value or range.

It will be further understood that various changes in the details, materials, and arrangements of the parts which have been described and illustrated in order to explain embodiments of this invention may be made by those skilled in the art without departing from embodiments of the invention encompassed by the following claims.

In this specification including any claims, the term “each” may be used to refer to one or more specified characteristics of a plurality of previously recited elements or steps. When used with the open-ended term “comprising,” the recitation of the term “each” does not exclude additional, unrecited elements or steps. Thus, it will be understood that an apparatus may have additional, unrecited elements and a method may have additional, unrecited steps, where the additional, unrecited elements or steps do not have the one or more specified characteristics.

The use of figure numbers and/or figure reference labels in the claims is intended to identify one or more possible embodiments of the claimed subject matter in order to facilitate the interpretation of the claims. Such use is not to be construed as necessarily limiting the scope of those claims to the embodiments shown in the corresponding figures.

Reference herein to “one embodiment” or “an embodiment” means that a particular feature, structure, or characteristic described in connection with the embodiment can be included in at least one embodiment of the invention. The appearances of the phrase “in one embodiment” in various places in the specification are not necessarily all referring to the same embodiment, nor are separate or alternative embodiments necessarily mutually exclusive of other embodiments. The same applies to the term “implementation.”

The embodiments covered by the claims in this application are limited to embodiments that (1) are enabled by this specification and (2) correspond to statutory subject matter. Non-enabled embodiments and embodiments that correspond to non-statutory subject matter are explicitly disclaimed even if they fall within the scope of the claims.

1. A power converter that converts a digital input signal into an output power signal, the power converter comprising:
a digital signal processor that processes the digital input signal to generate one or more copies of a multi-bit digital signal;
one or more multi-bit current generators, each converting a corresponding copy of the multi-bit digital signal into a corresponding differential current signal; and
one or more differential-to-single-ended converters, each converting a corresponding differential current signal into a single-ended bipolar signal.

2. The power converter of claim 1, wherein:
the digital input signal is a complex baseband signal comprising in-phase I_{IN} and quadrature Q_{IN} components;
each copy of the multi-bit digital signal is a multi-bit RF signal;
the digital signal processor converts the complex baseband signal into the one or more copies of the multi-bit RF signal; and
the output power signal is an RF power signal.

3. The power converter of claim 1, wherein:
the digital signal processor processes the digital input signal to generate a single copy of the multi-bit digital signal;
the power converter comprises:
a single multi-bit current generator converting the single copy of the multi-bit digital signal into a single differential current signal; and
a single differential-to-single-ended converter converting the single differential current signal into a single single-ended bipolar signal, wherein the single single-ended bipolar signal is the output power signal.

4. The power converter of claim 1, wherein:
the digital signal processor processes the digital input signal to generate multiple copies of the multi-bit digital signal;
the power converter comprises multiple multi-bit current generators and multiple differential-to-single-ended converters; and
the power converter further comprises a combiner that combines the multiple single-ended bipolar signals to generate the output power signal.

5. The power converter of claim 1, wherein each multi-bit current generator comprises:
a set of switched current sources, each receiving a different bit of the multi-bit digital signal and selectively providing a current signal based on the value and weight of the received bit;
a current summation node that sums the different current signals from the set of switched current sources to generate a unipolar summed current signal; and
a single-ended-to-differential converter that converts the unipolar summed current signal into the corresponding differential current signal.

6. The power converter of claim 5, wherein each switched current source comprises a constant current source connected in series to a switch controlled by the corresponding bit of the multi-bit digital signal.

7. The power converter of claim 1, wherein each differential-to-single-ended converter is a balun converter.

8. The power converter of claim 1, further comprising:
at least two voltage supplies providing at least two different supply voltage levels; and
a switch controlled by the digital signal processor to select, based on the magnitude of the multi-bit digital signal, one of the at least two voltage supplies to drive each multi-bit current generator.

9. The power converter of claim 1, wherein:
the digital signal processor is implemented in a first semiconductor technology; and
the one or more multi-bit current generators are implemented in a second semiconductor technology different from the first semiconductor technology.

10. The power converter of claim 9, wherein:
the first semiconductor technology is a silicon technology; and
the second semiconductor technology is a non-silicon technology.

11. The power converter of claim 10, wherein the non-silicon technology is a gallium-arsenide, gallium-nitride, or indium phosphide technology.

12. The power converter of claim 1, wherein:
the digital input signal is a complex baseband signal comprising in-phase I_{IN} and quadrature Q_{IN} components;
each copy of the multi-bit digital signal is a multi-bit RF signal;
the digital signal processor converts the complex baseband signal into the one or more copies of the multi-bit RF signal;
the output power signal is an RF power signal,
each multi-bit current generator comprises:
a set of switched current sources, each receiving a different bit of the multi-bit digital signal and selectively providing a current signal based on the value and weight of the received bit, wherein each switched current source comprises a constant current source connected in series to a switch controlled by the corresponding bit of the multi-bit digital signal;
a current summation node that sums the different current signals from the set of switched current sources to generate a unipolar summed current signal; and
a single-ended-to-differential converter that converts the unipolar summed current signal into the corresponding differential current signal,
each differential-to-single-ended converter is a balun converter;
further comprising:
at least two voltage supplies providing at least two different supply voltage levels; and
a switch controlled by the digital signal processor to select, based on the magnitude of the multi-bit digital signal, one of the at least two voltage supplies to drive each multi-bit current generator;
the digital signal processor is implemented in a first, silicon semiconductor technology;
and the one or more multi-bit current generators are implemented in a second, non-silicon semiconductor technology different from the first, silicon semiconductor technology, wherein the non-silicon technology is a gallium-arsenide, gallium-nitride, or indium phosphide technology.

13. The power converter of claim 12, wherein:
the digital signal processor processes the digital input signal to generate a single copy of the multi-bit digital signal;
the power converter comprises:
a single multi-bit current generator converting the single copy of the multi-bit digital signal into a single differential current signal; and
a single differential-to-single-ended converter converting the single differential current signal into a single single-ended bipolar signal, wherein the single single-ended bipolar signal is the output power signal.

14. The power converter of claim 12, wherein:
the digital signal processor processes the digital input signal to generate multiple copies of the multi-bit digital signal;
the power converter comprises multiple multi-bit current generators and multiple differential-to-single-ended converters; and
the power converter further comprises a combiner that combines the multiple single-ended bipolar signals to generate the output power signal.
